(19) United States
(12) Patent Application Publication
(10) Pub. No.: US 2026/0186518 A1
(43) Pub. Date: Jul. 2, 2026

(54) VOLTAGE REGULATOR DETECTOR FOR WIDE VOLTAGE OPERATION

(71) Applicant: IM2 Solutions, Inc., Pleasanton, CA (US)

(72) Inventor: Tim LAO, Sacramento, CA (US)

(21) Appl. No.: 19/439,272

(22) Filed: Jan. 2, 2026

Related U.S. Application Data
(60) Provisional application No. 63/741,113, filed on Jan. 1, 2025.
(60) Provisional application No. 63/741,112, filed on Jan. 1, 2025.

(51) Int. Cl. G05F 1/618; G01R 19/165; G05F 1/46

(52) U.S. Cl. CPC G05F 1/618; G01R 19/16523; G01R 19/16576; G05F 1/468

(57) ABSTRACT

Certain embodiments of present disclosure provide a voltage detector including input gates configured to receive an input voltage and a reference voltage, and input devices and protection devices each having a low threshold voltage. The voltage detector further includes a current source, first and second diode-connected loads, first and second pre-charging devices, and an input differential amplifier made of devices having threshold voltages significantly higher than the low threshold voltages. The voltage detector is operable with a supply voltage about twice as high as an upper limit of an operating voltage range for the input devices. The voltage detector in an “ON” state is configured to drive an output voltage at the output of the differential amplifier higher or lower in response to the input voltage being driven above or below the reference voltage, respectively. Also provided herein is a voltage regulator including the voltage detector.

### CROSS REFERENCE TO RELATED APPLICATIONS

The present application claims the benefit of priority to U.S. Provisional Patent Application No. 63/741,113, filed Jan. 1, 2025, entitled “Voltage Regulator Detector for Wide Voltage Operation,” and U.S. Provisional Patent Application No. 63/741,112, filed Jan. 1, 2025, entitled “High-Voltage Drivers Using Low-Voltage Devices with Protection Circuitry for High Endurance Operation,” each of which is incorporated herein by reference in its entirety. The present application is related to U.S. patent application Ser. No. 19/363,553, filed Oct. 20, 2025, and U.S. Patent Application Attorney Docket No. IM003-03US, entitled “High-Voltage Drivers Using Low-Voltage Devices with Protection Circuitry for High Endurance Operation,” filed on even date herewith, each of which is incorporated herein by reference in its entirety.

### FIELD

The present application is related to electronic circuits, and more particularly to high-voltage drivers using low-voltage devices with protection circuitry for high endurance operation.

### BACKGROUND

As process nodes become smaller and more advanced, the regulated voltage for core circuitry in an integrated circuit device also becomes progressively lower, which can drop below the threshold, Vth, of input gates configured to operate at a higher voltage than the core circuitry. In this case, the high voltage input gates may not be suitable for the low regulated internal voltage because the low regulated internal voltage may not be higher than the threshold voltage, Vth, of the input gates to turn on the high voltage input gates, especially at some process-voltage-temperature (PVT) corner conditions.

### SUMMARY

A wide voltage detector according to some embodiments uses core devices, instead of high voltage devices, to form input gates. The core devices have lower threshold voltage, Vth, and lower operating voltage range and limit, e.g., 0.8 v-1.1 v. Furthermore, the input gates also include low voltage (e.g., ˜1.8 v) under-drive IO devices as protection devices to protect the core devices from source to drain VDS breakdown caused by higher operating voltages.

According to certain embodiments, a voltage detector includes first and second inputs configured to receive an input voltage and a reference voltage, respectively, and input devices and protection devices each having a lower threshold voltage. The voltage detector further includes a current source, first and second diode-connected loads, first and second pre-charging devices, and an input differential amplifier made of devices having threshold voltages significantly higher than the lower threshold voltages. The voltage detector is operable with a supply voltage about twice as high as an upper limit of an operating voltage range for the input devices. The voltage detector in an “ON” state is configured to drive an output voltage at the output of the differential amplifier higher or lower in response to the input voltage being driven above or below the reference voltage, respectively.

According to certain embodiments. a voltage regulator includes the voltage detector and a driver device having a control terminal, and first and second current-carrying terminals. The first current-carrying terminal of the driver device is configured to be coupled to a supply voltage terminal of the voltage regulator, and the second current-carrying terminal of the driver device is coupled to the first input of the voltage regulator. The voltage regulator further includes a plurality of invertors coupled in series between the voltage detector and the driver device, the plurality of inverters including at least a first inverter and a last inventor, the first invertor having an input coupled to the output of the input differential amplifier and the last invertor having an output coupled to the control terminal of the driver device. In some embodiments, the voltage regulator is configured to cause the input voltage to oscillate around the reference voltage.

Certain embodiments provide a method of voltage regulation at a voltage detector including a plurality of metal-oxide-semiconductor (MOS) devices each having a control terminal, and first and second current-carrying terminals. The plurality of MOS devices includes first and second input devices, a bias device coupled to the first current-carrying terminal of each of the first and second input devices, a first protection device coupled to the second current-carrying terminal of the first input device, and a second protection device coupled to the second current-carrying terminal of the second input device. The method comprises applying a protection voltage to the control terminals of first and second protection devices, applying a bias voltage to the control terminal of the bias device, applying a reference voltage to the control terminal of the first input device, applying an enable signal to turn on a current path via the bias device, and driving an input voltage to the control terminal of the second input device. In some embodiments, an output voltage of the voltage detector is driven lower in response to the input voltage being driven below the reference voltage and is driven higher in response to the input voltage being driven above the reference voltage.

### BRIEF DESCRIPTION OF THE DRAWINGS

FIG. 1 is a circuit diagram of a wide voltage detector with input protection for voltage regulation of an internal voltage VDD according to certain embodiments.

FIG. 2 is a schematic block diagram of a voltage regulator including the wide voltage detector shown in FIG. 1 according to certain embodiments.

FIG. 3 is a waveform diagram illustrating the voltage regulator operating at a lower range of an external power supply voltage XVDD (e.g., XVDD˜2.4 v) according to certain embodiments.

FIG. 4 is a waveform diagram illustrating the voltage regulator operating at the upper range of XVDD (e.g., XVDD˜3.8 v) according to certain embodiments.

FIG. 5 is a waveform diagram showing a protection level for the input gates during voltage regulator operation according to certain embodiments.

### DESCRIPTION OF THE EMBODIMENTS

### Main Power and Signal Description

Power and ground:
   XVDD—External power supply (e.g., XVDD˜2.4 v-3.6 v).
   VDD—Regulated internal voltage for core devices (0.9 v).
   VSS—ground.
Signals:
   VREF18—constant gate voltage (e.g., 1.8V) for protection devices
   VBIAS—Bias voltage for wide voltage detector
   EN/ENH—Enable signal for wide voltage detector
   VREF/INN—reference voltage for wide voltage detector
   OUT/OUT0—Detector Output

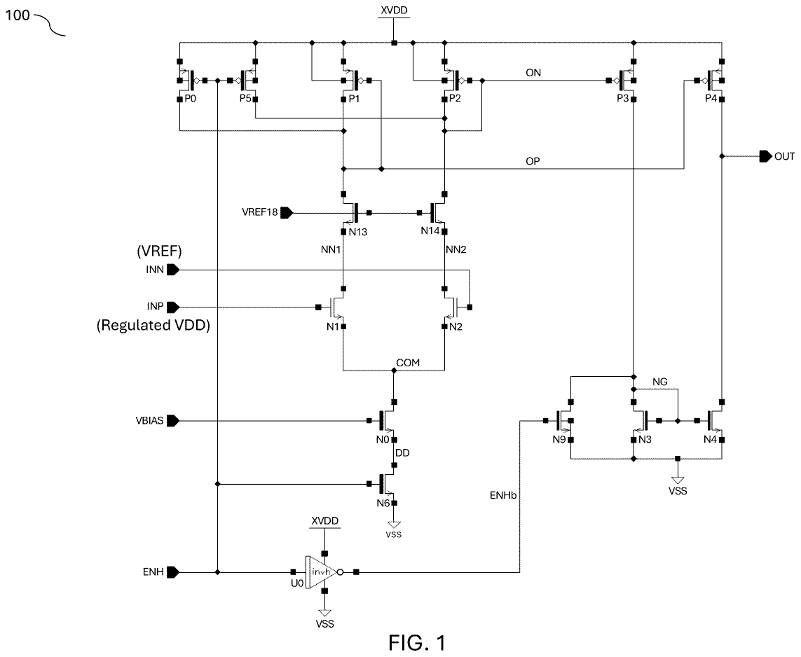

FIG. 1 illustrates main circuitry of a wide voltage detector (WVD) 100 according to certain embodiments. As shown, the wide voltage detector 100 includes a plurality of p-type metal-oxide-semiconductor (PMOS) devices, e.g., PMOS devices P0, P1, P2, P3, P4, and P5, a plurality of n-type metal-oxide-semiconductor (NMOS) devices, e.g., NMOS devices N0, N1, N2, N3, N4, N6, N9, N13 and N14, and an inverter U0. The wide voltage detector 100 is operable with XVDD varying over a wide range, e.g., between 2.4 v to 3.8 v, and is thus called wide voltage detector. Regardless of the XVDD setting anywhere between 2.4 v to 3.8 v, WVD 100 is able to sense differential input, INP and INN, and generate a corresponding output OUT.

As shown, P0, P1, P2, P3, P4, and P5 each has its source coupled to an external power supply voltage XVDD. Since XVDD is a high voltage power supply, each of the PMOS devices P0, P1, P2, P3, P4, and P5 connected to XVDD is also a high voltage device that can tolerate voltage up to 3.8 v across any two of its source, drain, and gate terminals. For example, the voltage between gate and source (VGS or VSG), the voltage between gate and drain (VGD or VDG), and the voltage between source and drain (VSD or VDS) for the each of P0, P1, P2, P3, P4 and P5 and some of the NMOS devices (except the core devices) can be in the range of 0 v to 3.6 v. As shown in FIG. 1, the gates of P1 and P4 are tied to form an OP node, and the gates of P2 and P3 are tied to form an ON node. OP and ON nodes are also high voltage nodes.

To regulate an internal voltage VDD, an input (INN) of the WVD 100 can receive a reference voltage VREF, and another input (INP) of the WVD 100 can receive a regulated internal voltage VDD (0.9 v). VREF (INN) is an adjustable reference voltage between 0.8 v and 1.1 v. At a default setting, VREF is a stable reference voltage at a steady level (e.g., 0.9 v). The detector 100 can be used by a voltage regulator, as it attempts to regulate the internal VDD to match the target VREF.

Normally, high voltage devices are used for input gates for the detector inputs (INN, INP). Comparing to core devices, which have threshold voltage(s) (Vth) in the range of, for example, 0.25 v-0.3 v, high voltage devices typically have higher threshold voltage(s), which can be in the range of, e.g., 0.6 v-0.7 v. As process nodes become smaller and more advanced, the regulated voltage for core circuitry in an integrated circuit device also becomes progressively lower, which can come close to the threshold, Vth, of input gates configured to operate at a higher voltage than the core circuitry. As a result, the high voltage input gates may not be suitable for low regulated internal voltage because the low regulated internal voltage may not be high enough to turn on the high voltage input gates, especially at some process-voltage-temperature (PVT) corner conditions.

Thus, instead of using high voltage devices as input gates, the wide voltage detector 100 uses core devices (N1, N2) as input gates. Core devices N1 and N2 have lower threshold voltage, Vth, and lower upper limit (e.g., 0.8 v-1.1 v) for its operating voltage. For example, the voltage between gate and source (VGS or VSG), the voltage between gate and drain (VGD or VDG) and the voltage between source and drain (VSD or VDS) for the core devices need to be kept in the range of 0 v to 1.0 v. Since the gates of these input core devices are connected to VREF (0.9 v) and the regulated internal voltage VDD (0.9 v), the VGS limit of core devices is met.

The source and drain of input core devices N1 and N2 cannot be connected directly to OP or ON, which are high voltage nodes and can be at a voltage as high as, e.g., 3V, which would exceed the VDS limit of core devices N1 and N2. To prevent that, the detector 100 further includes lower voltage (e.g., 1.8 v) underdrive NMOS IO devices (N13, N14), which can be placed between the core devices N1 and N2 and the OP and ON nodes to protect the core devices N1 and N2 from source to drain VDS breakdown. The gates of the low voltage underdrive IO devices N13 and N14 are connected to a constant and stable voltage (e.g., 1.8 v). In some embodiments, one of the source and drain of N13 is connected to the OP node, and the other one of the source and drain of N13 is connected to the source or drain of N1 via node NN1. Likewise, one of the source and drain of N14 is connected to the ON node, and the other one of the source and drain of N14 is connected to the source or drain of N2 via node NN2. In some embodiments, each of N13 and N14 is an “underdrive MOS transistor” (Metal Oxide Semiconductor Field Effect Transistor) that is operated with VGS (voltage between gate and source) significantly below its threshold voltage, meaning that it is not fully turned on and conducts a very small current, essentially operating in a partially “off” state. With this configuration, the VDS limit of both the IO protection devices N13, N14, and the input core devices N1, N2, can be met.

In some embodiments, as shown in FIG. 1, N1, N2, N13, N14 form the input gates with breakdown protection for the wide voltage detector 100. In addition, P1, P2, are PMOS diode connected loads, P3, P4, N3, N4 form a P input differential amplifier with rail to rail output, N0 is a current source, P0, P5 are pre-charging devices to pre-charge ON, OP, N9 is a pull down device to bring node NG of the P input differential amplifier to VSS, and OUT is the detector output and is configured to be connected to an inverter (not shown in FIG. 1) with a small gate capacitance.

Referring to FIG. 1, to put the wide voltage detector 100 in an OFF state, ENH is set to low, which disables the detector 100 by turning off N6 and cutting off the source current path for the input core devices N1 and N2. ENH being low also forces P0 and P5 to pre-charge OP and ON to XVDD, which turns off P3 and P4. Further ENH being low also drives (through the inverter U0) ENHb high and NG low, thus turning off N3 and N4. With P4 and N4 off, the OUT node can be driven to high at upper level without contention.

Referring still to FIG. 1, to put the detector 100 in an ON state, ENH is set to high after VREF18, VBIAS, and VREF are properly set and applied in advance. This enables the detector 100 by turning on N6 to provide a source current path for N1 and N2. ENH being high also turns off P0 and P5 and disables OP and ON pre-charge. Further, ENH being high also drives ENHb low and turns off N9. VBIAS at 0.75 v forces N0 to be a current source, VREF18 is a constant (e.g., stable at 1.8 v) and is connected to the gate of each of the protection devices N13 and N14, and VREF is a reference voltage (e.g., 0.9 v).

In such setting, when the regulated internal voltage VDD (INP) is driven below VREF (INN), the ON node will be slightly lower than the OP node, so VSG (P4)<VSG (P3). Thus, the current through P4 is less than the current through P3, i.e., i(P4)<i(P3). Now, since N9 is turned off, i(P3)=i(N3), and i(N4) mirrors i(N3). So, i(P3)=i(N4), and i(P4)<i(N4). As a result, there would be current discharging from OUT node to N4 which will drive the OUT node lower, since the OUT node is connected to a small gate capacitance of an inverter (not shown in FIG. 1) external to the voltage detector 100.

When the regulated internal voltage VDD (INP) is driven above VREF (INN), the voltage at the ON node will be slightly higher than the voltage at the OP node, so VSG (P4)>VSG (P3), or i(P4)>i(P3). Considering that i(P3)=i(N3), and i(N4) mirrors i(N3), VSG (P4)>VSG (P3) leads to i(P4)>i(N4), meaning that there will be a current charging the OUT node which will drive the OUT node higher.

Thus, the wide voltage detector is operable to regulate the internal VDD to match the target VREF at the OUT node.

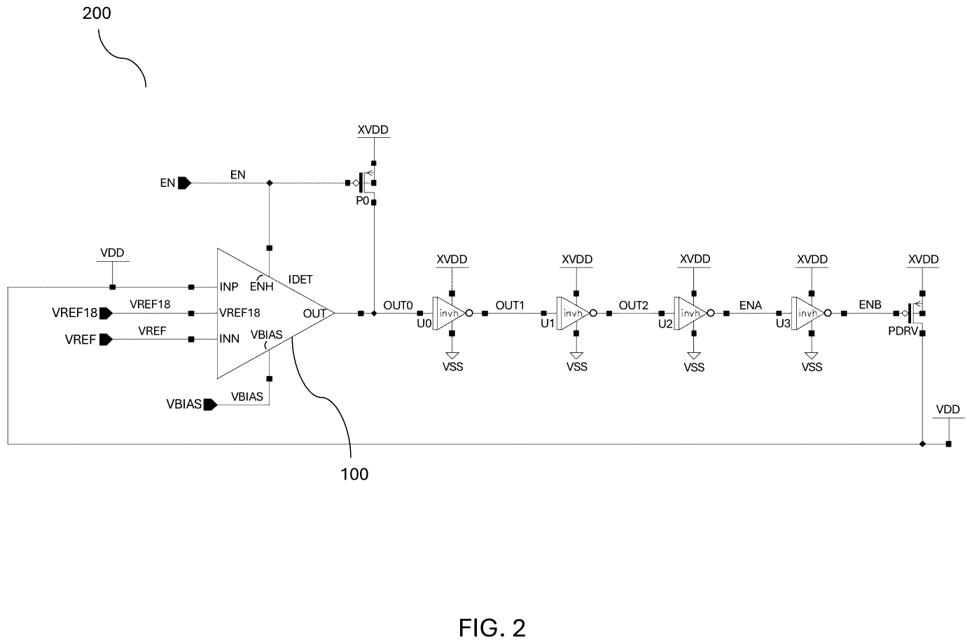

FIG. 2 illustrates a voltage regulator 200 using the wide voltage detector 100 to regulate the internal voltage VDD according to certain embodiments. As shown in FIG. 2, the voltage regulator 200 can be put in an OFF state by setting EN=low, which forces P4 and N4 of the detector 100 off, and turns on P0 of the regulator to drive OUT0 to high, which in turn would turn off PMOS driver device PDRV. In this case, VDD is no longer regulated or driven.

To put the regulator in an ON state, EN is set to high after VREF18, VBIAS, and VREF are properly set and applied in advance. When the regulated internal voltage VDD (INP) is driven below VREF (INN), OUT0→low, ENB→low, PDRV on, which will drive VDD higher until it crosses above VREF. When the regulated internal voltage VDD (INP) is driven above VREF (INN), OUT0→high, ENB→high, PDRV is off. Thus, the current consumption of VDD will drive VDD lower until it crosses below VREF.

Thus, the voltage regulator 200 causes the regulated VDD to oscillate around VREF.

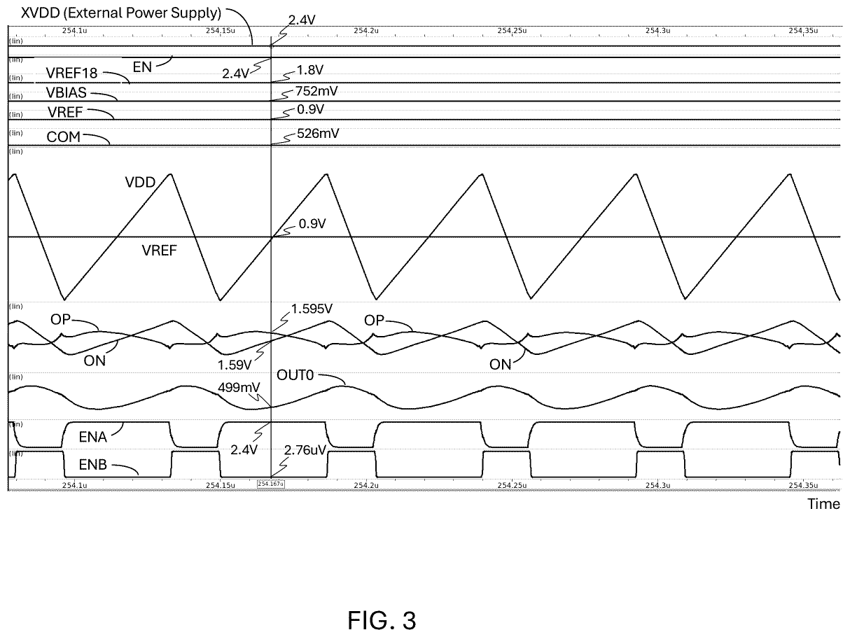

FIG. 3 is a waveform diagram showing VDD being driven to above and below VREF and the end result of the regulated VDD oscillating around VREF in the case that XVDD=2.4 v, in the lower range of the external power supply.

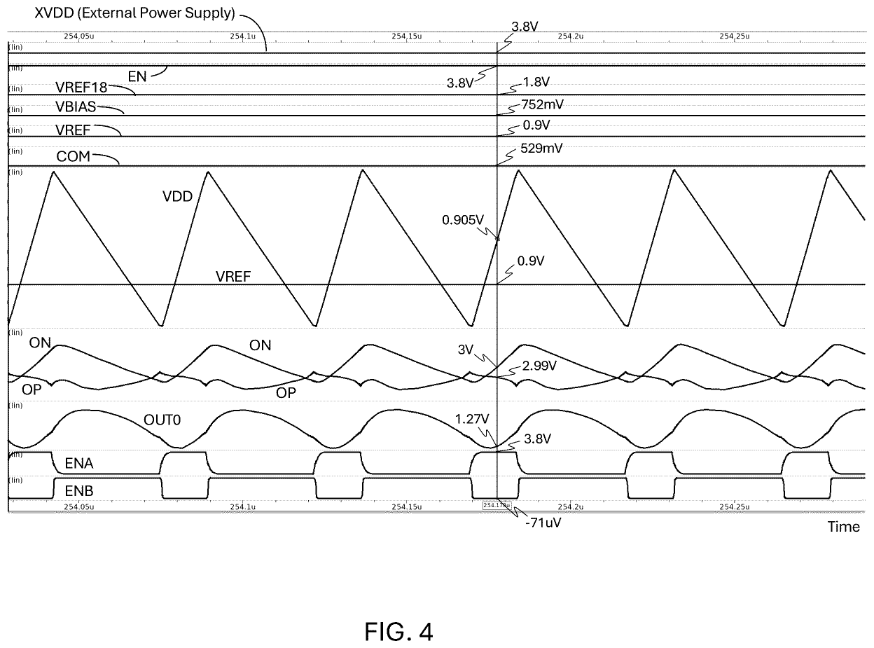

FIG. 4 is a waveform diagram showing VDD being driven to above and below VREF and the end result of the regulated VDD oscillating around VREF in the case that XVDD=3.8 v, in the upper range of the external power supply.

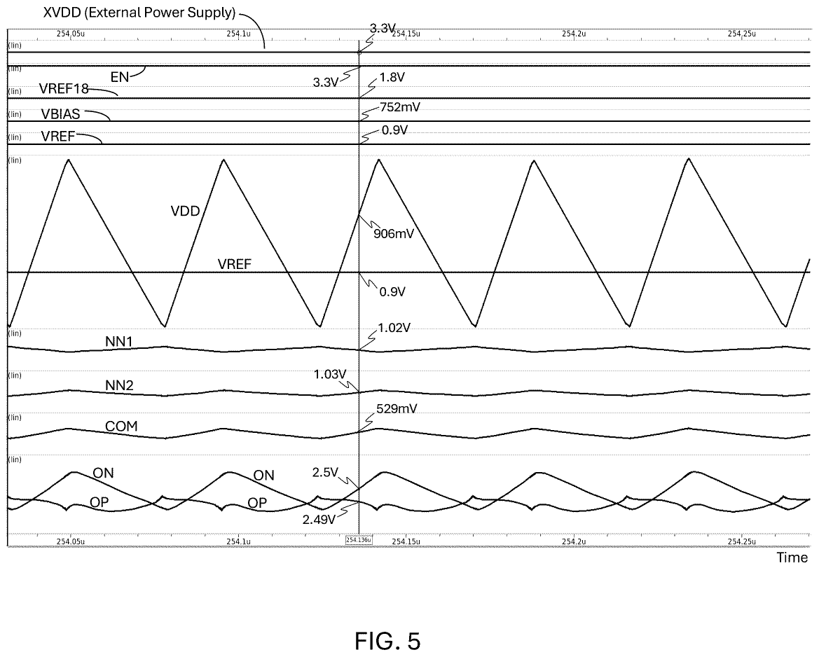

FIG. 5 shows the values of nodes around the input core gates and the protection devices, demonstrating that these devices are operating within the VGS, VGD, and VDS limits of the core devices N1 and N2 and the 1.8 v underdrive IO devices N13 and N14. As shown in FIG. 5, since the regulated VDD (e.g., ˜0.9 v) and VREF (e.g., ˜0.9 v) are applied to the input gates (N1, N2), the VGS limit requirement (VGS<=1.1 v) of the core devices is met.

Also, since a constant voltage, VREF18 (e.g., ˜1.8 v), is applied to the gate of the protection devices (N13, N14), which are of, e.g., 1.8 v, underdrive IO device type, the VGS limit requirement (VGS<=2.0 v) of this device type is also met.

Further, for the detector, OP and ON is operating near 2.5 v. Due to the gate of the protection devices (N13, N14) being set at 1.8 v, node NN1 and NN2 would be dropped to VREF18 (1.8 v)−Vth, where Vth is the threshold of N13, N14. As seen from the waveform in FIG. 5, there is a voltage drop from OP, ON=2.5 v to NN1, NN2=1.0 v. Therefore, the VDS of N13, N14 would be about 1.5 v, which can satisfy the VDS requirement (VDS<=2.0 v) of the 1.8 v underdrive IO device type.

Since NN1, NN2 nodes are now operating at around 1.0 v, the VDS requirement (VDS<=1.1 v) of the input core gate devices N1, N2 is also met.

Meeting the VGS and VDS requirements of both of these core devices types helps to protect these devices from dielectric breakdown and source-drain VDS breakdown.

What is claimed is:

1. A voltage detector, comprising:
first and second inputs configured to receive an input voltage and a reference voltage, respectively;
first and second input devices each having a control terminal, and first and second current-carrying terminals, wherein the control terminals of the first and second input devices are respectively coupled to the first and second inputs;
first and second protection devices each having a control terminal, and first and second current-carrying terminals, wherein the first current-carrying terminals of the first and second protection devices are respectively coupled to the second current-carrying terminals of the first and second input devices;
a current source coupled to the first current-carrying terminal of each of the first and second input devices;
first and second diode-connected loads, wherein each of the first and second diode-connected loads is coupled between a supply voltage terminal and the second current-carrying terminal of a respective protection device;
first and second pre-charging devices configured to pre-charge first and second nodes, respectively, the first node being a node between the first diode-connected load and the first protection device, the second node being a node between the second diode-connected load and the second protection device;
an input differential amplifier having a first input coupled to the first node, a second input coupled to the second node, and an output;
wherein the current source, the first and second diode-connected loads, the first and second precharging devices and the input differential amplifier each includes one or more high voltage devices having a threshold voltage greater than or equal to a first voltage;
wherein the first and second input devices and the first and second protection devices are core devices, each respective core device of the core devices having a respective threshold voltage significantly lower than the first voltage
wherein the voltage detector is configurable to be in an “ON” state, and the voltage detector in the “ON” state is configured to drive an output voltage at the output of the differential amplifier lower in response to the input voltage being driven below the reference voltage, and to drive the output voltage higher in response to the input voltage being driven above the reference voltage.

2. The voltage detector of claim 1, further comprising a third input coupled to the control terminal of each of the first and second protection devices and configured to receive an intermediate voltage about halfway between a supply voltage applied to the supply voltage terminal and ground.

3. The voltage detector of claim 2, further comprising a fourth input coupled to a first control terminal of the current source and configured to receive a bias voltage.

4. The voltage detector of claim 3, further comprising an enable terminal coupled to a second control terminal of the current source, and to a control terminal of the first and second precharging devices.

5. The voltage detector of claim 4, wherein the enable terminal is further coupled to a control terminal of the input differential amplifier via an inverter.

6. The voltage detector of claim 5, wherein, in response to a supply voltage being applied to the supply voltage terminal, the intermediate voltage being applied to the third input, and the bias voltage being applied to the fourth input, and the enable input being at a first level, a current path through the current source is cut off, the first and second precharge devices are turned on to precharge the first and second nodes to the supply voltage, and the output of the differential amplifier is disconnected from both the supply voltage terminal and ground.

7. The voltage detector of claim 5, wherein, in response to a supply voltage being applied to the supply voltage terminal, the intermediate voltage being applied to the third input, and the bias voltage being applied to the fourth input, and the enable input being at a second level, the current source is turned on, the first and second precharge devices are turned off to disable precharging of the first and second nodes, and the output of the input differential amplifier is driven lower or higher in response to the input voltage being driven above or below the reference voltage, respectively.

8. The voltage detector of claim 2, wherein the supply voltage terminal is configured to be coupled to a supply voltage significantly higher than an upper limit of an operating voltage range of any of the core devices.

9. The voltage detector of claim 6, wherein voltage detector is operable to output via the output of the input differential amplifier a voltage signal spanning an entire range between the supply voltage and ground.

10. A voltage regulator, comprising:
a voltage detector according to claim 1;
a driver device having a control terminal, and first and second current-carrying terminals, wherein the first current-carrying terminal of the driver device is coupled to a supply voltage terminal of the voltage regulator, and the second current-carrying terminal of the driver device is coupled to the first input of the voltage regulator; and
a plurality of invertors coupled in series between the voltage detector and the driver device, the plurality of inverters including at least a first inverter and a last inventor, the first invertor having an input coupled to the output of the input differential amplifier and the last invertor having an output coupled to the control terminal of the driver device.

11. The voltage regulator of claim 10, wherein the voltage detector further comprises an enable terminal coupled to a second control terminal of the current source, and to a control terminal of the first and second precharging devices.

12. The voltage regulator of claim 11, further comprising an output control device having a control terminal coupled to an enable input of the voltage detector, a first current-carrying terminal coupled to an external power supply terminal of the voltage regulator, and a second current-carrying terminal coupled to the output of the input differential amplifier.

13. The voltage regulator of claim 12, wherein the voltage regulator is configurable to be put in an OFF state by setting a voltage at the enable input to a predetermined level, causing the output control device to turn on to drive the output of the input differential amplifier to a voltage at the external power supply terminal.

14. The voltage regulator of claim 10, wherein the plurality of inverters including at least four inverters coupled in series.

15. The voltage regulator of claim 10, wherein the voltage regulator is configurable to be in an ON state in which a regulated voltage at the second current-carrying terminal of the driver device oscillates around the reference voltage.

16. A method of voltage regulation, comprising:
at voltage detector including a plurality of metal-oxide-semiconductor (MOS) devices each having a control terminal, and first and second current-carrying terminals, the plurality of MOS devices including first and second input devices, a bias device coupled to the first current-carrying terminal of each of the first and second input devices, a first protection device coupled to the second current-carrying terminal of the first input device, and a second protection device coupled to the second current-carrying terminal of the second input device,
applying a protection voltage to the control terminals of first and second protection devices;
applying a bias voltage to the control terminal of the bias device;
applying a reference voltage to the control terminal of the first input device;
applying an enable signal to turn on a current path via the bias device; and
driving an input voltage to the control terminal of the second input device;
wherein an output voltage of the voltage detector is driven lower in response to the input voltage being driven below the reference voltage, and is driven higher in response to the input voltage being driven above the reference voltage.

17. The method of claim 16, wherein the voltage detector is coupled to an external power supply having a supply voltage that is higher than twice the reference voltage.

18. The method of claim 17, wherein the protection voltage is higher than the reference voltage and lower than the supply voltage.

19. The method of claim 18, wherein the bias voltage is less than the reference voltage.

20. The method of claim 16, wherein the protection devices are underdriven devices.
